(19) United States
(12) Patent Application Publication
(10) Pub. No.: US 2025/0280491 A1
(43) Pub. Date: Sep. 4, 2025

(54) RADIO FREQUENCY MODULE AND COMMUNICATION DEVICE

(71) Applicant: Murata Manufacturing Co., Ltd., Nagaokakyo-shi (JP)

(72) Inventors: Mayuka ONO, Nagaokakyo-shi (JP); Motoji TSUDA, Nagaokakyo-shi (JP)

(73) Assignee: Murata Manufacturing Co., Ltd., Nagaokakyo-shi (JP)

(21) Appl. No.: 19/063,424

(22) Filed: Feb. 26, 2025

(30) Foreign Application Priority Data
Mar. 1, 2024 (JP) 2024-031207

(51) Int. Cl. H05K 1/02; H05K 1/03; H05K 1/11

(52) U.S. Cl. CPC H05K 1/0237; H05K 1/0216; H05K 1/0306; H05K 1/11; H05K 2201/0275

(57) ABSTRACT

In a radio frequency module, a resin layer is disposed on a first main surface of a mounting substrate and covers electronic components. An external shield layer covers at least part of an outer peripheral surface of the mounting substrate and the resin layer. The mounting substrate includes a first dielectric layer, a second dielectric layer, and ground electrodes. The first dielectric layer contains a resin and does not contain a glass fiber. The second dielectric layer overlaps the first dielectric layer in a thickness direction of the mounting substrate and is in contact with the first dielectric layer. The second dielectric layer contains a resin and does not contain a glass fiber. The ground electrodes are interposed between the first dielectric layer and the second dielectric layer. The ground electrodes are each directly connected to the external shield layer.

### CROSS-REFERENCE TO RELATED APPLICATION

This application claims priority to Japanese Patent Application No. JP 2024-031207 filed on Mar. 1, 2024. The entire contents of the above-identified applications, including the specifications, drawings and claims, are incorporated herein by reference in their entirety.

### BACKGROUND OF THE DISCLOSURE

### 1. Field of the Disclosure

The present disclosure generally relates to a radio frequency module and a communication device, and more specifically, to a radio frequency module including a mounting substrate and a communication device including the radio frequency module.

### 2. Description of the Related Art

Japanese Unexamined Patent Application Publication No. 2015-44397 discloses a copper-clad laminate for printed circuit boards. The copper-clad laminate includes a complex in which glass fibers are formed on both surfaces of a prepreg. The complex is located between a resin layer of first resin coated copper foil (first RCC) and a resin layer of second resin coated copper foil (second RCC).

Japanese Unexamined Patent Application Publication No. 2015-44397 discloses a printed circuit board in which a circuit pattern is formed on copper foil of the copper-clad laminate to be applied.

### SUMMARY OF THE DISCLOSURE

In a radio frequency module including a mounting substrate and an electronic component, an improvement in reliability of shielding properties is preferred in some cases.

A feature of the present disclosure is to provide a radio frequency module capable of improving reliability of shielding properties and a communication device.

A radio frequency module according to an aspect of the present disclosure includes a mounting substrate, an electronic component, a resin layer, and an external shield layer. The mounting substrate has a first main surface and a second main surface opposing each other. The electronic component is disposed on the first main surface of the mounting substrate. The resin layer is disposed on the first main surface of the mounting substrate and covers the electronic component. The external shield layer covers at least part of an outer peripheral surface of the mounting substrate and covers the resin layer. The mounting substrate includes a first dielectric layer, a second dielectric layer, and a ground electrode. The first dielectric layer contains a resin and does not contain a glass fiber. The second dielectric layer overlaps the first dielectric layer in a thickness direction of the mounting substrate and is in contact with the first dielectric layer. The second dielectric layer contains a resin and does not contain a glass fiber. The ground electrode is interposed between the first dielectric layer and the second dielectric layer. The ground electrode is directly connected to the external shield layer.

A communication device according to an aspect of the present disclosure includes the radio frequency module of the above-mentioned aspect and a signal processing circuit. The signal processing circuit is connected to the radio frequency module.

The radio frequency module and the communication device according to the above-mentioned aspects of the present disclosure can improve the reliability of shielding properties.

### BRIEF DESCRIPTION OF THE DRAWINGS

FIG. 1 is a cross-sectional view of a radio frequency module according to Embodiment 1;

FIG. 2 is a plan view of part of the radio frequency module;

FIG. 3 is a bottom view of part of the radio frequency module;

FIG. 4 is a cross-sectional view of a major part of the radio frequency module;

FIG. 5 is a block diagram of a communication device including the radio frequency module;

FIG. 6 is a cross-sectional view of a radio frequency module according to Embodiment 2;

FIG. 7 is a cross-sectional view of a radio frequency module according to Embodiment 3; and

FIG. 8 is a cross-sectional view of a radio frequency module according to Embodiment 4.

### DESCRIPTION OF THE PREFERRED EMBODIMENTS

Hereinafter, Embodiments 1 to 4 and the like will be described with reference to the drawings. The drawings referred to in the following Embodiments 1 to 4 and the like are schematic drawings, and the size and thickness of each constituent element in the drawings do not necessarily reflect actual dimensions, and the ratio of the size and the ratio of the thickness between constituent elements do not necessarily reflect actual dimensional ratios.

### Embodiment 1

### 1. Radio Frequency Module

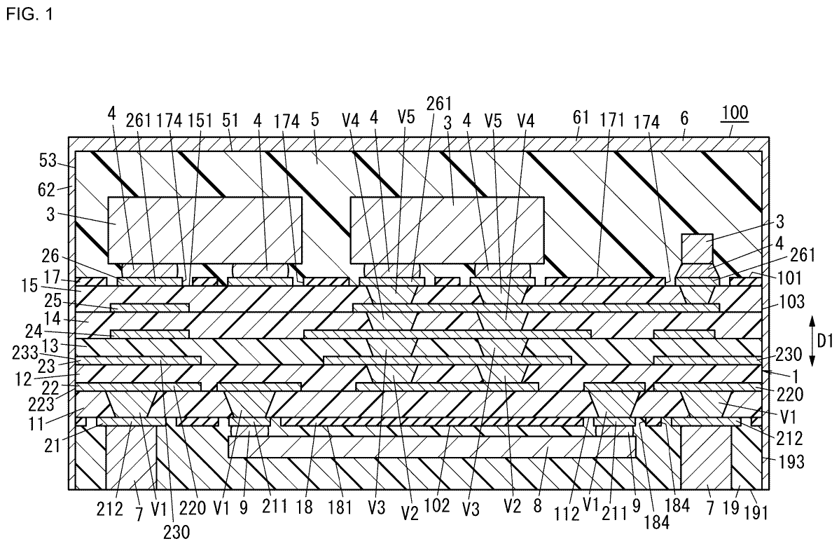

A radio frequency module 100 according to Embodiment 1 will be described with reference to FIGS. 1 to 4.

As illustrated in FIG. 1, the radio frequency module 100 according to Embodiment 1 includes a mounting substrate 1, a plurality of electronic components 3 (hereinafter, also referred to as first electronic components 3), a resin layer 5, and an external shield layer 6. The mounting substrate 1 has a first main surface 101 and a second main surface 102 opposing each other. The electronic components 3 are each disposed on the first main surface 101 of the mounting substrate 1. The resin layer 5 is disposed on the first main surface 101 of the mounting substrate 1 and covers the electronic components 3. The external shield layer 6 covers an outer peripheral surface 103 of the mounting substrate 1 and the resin layer 5. The mounting substrate 1 includes a first dielectric layer 11, a second dielectric layer 12, and two ground electrodes 220. The first dielectric layer 11 contains a resin and does not contain a glass fiber. The second dielectric layer 12 overlaps the first dielectric layer 11 in a thickness direction D1 of the mounting substrate 1 and is in contact with the first dielectric layer 11. The second dielectric layer 12 contains a resin and does not contain a glass fiber. The ground electrodes 220 are interposed between the first dielectric layer 11 and the second dielectric layer 12. In the radio frequency module 100, the ground electrodes 220 are each directly connected to the external shield layer 6.

The radio frequency module 100 further includes a plurality of external connection terminals 7 disposed on the second main surface 102 of the mounting substrate 1.

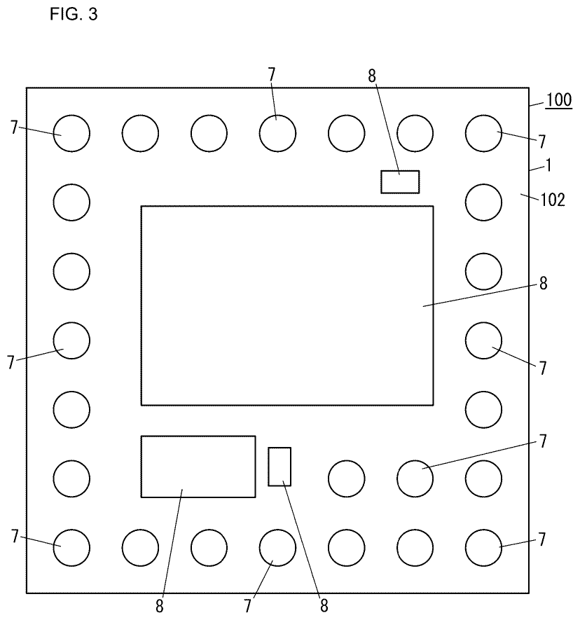

As illustrated in FIGS. 1 and 3, the radio frequency module 100 further includes a plurality of (four in FIG. 3) second electronic components 8 disposed on the second main surface 102 of the mounting substrate 1.

As illustrated in FIG. 1, the radio frequency module 100 further includes a second resin layer 19 different from a first resin layer 5 as the resin layer 5. The second resin layer 19 is disposed on the second main surface 102 of the mounting substrate 1 and covers the plurality of second electronic components 8.

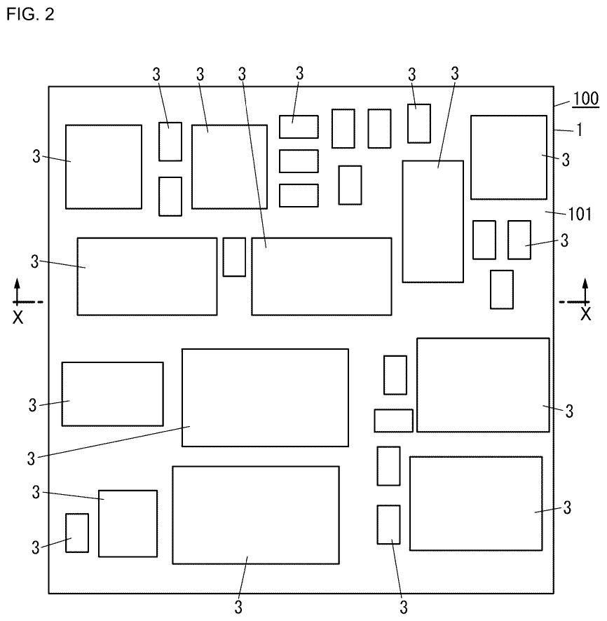

In the radio frequency module 100, the mounting substrate 1 further includes a first resist layer 17 and a second resist layer 18. A main surface 171 of the first resist layer 17 constitutes part of the first main surface 101 of the mounting substrate 1. A main surface 181 of the second resist layer 18 constitutes part of the second main surface 102 of the mounting substrate 1. FIG. 1 is a cross-sectional view corresponding to a cross section taken along a line X-X in FIG. 2. In FIG. 2, the first resin layer 5 and the external shield layer 6 are not illustrated. In FIG. 3, the second resin layer 19 and the external shield layer 6 are not illustrated.

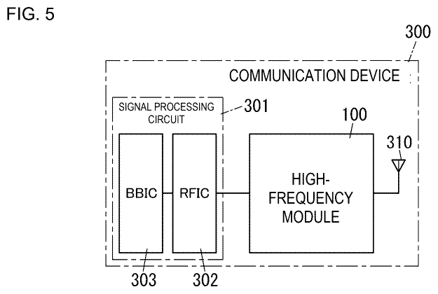

The radio frequency module 100 according to Embodiment 1 is used in, for example, a communication device 300 as illustrated in FIG. 5. The communication device 300 is, for example, a mobile phone (e.g., a smartphone), but is not limited thereto, and may be, for example, a wearable terminal (e.g., a smart watch). The radio frequency module 100 is a module that can support, for example, the fourth-generation mobile communication (4G) standard or the fifth-generation mobile communication (5G) standard. The 4G standard is, for example, the Third Generation Partnership Project (3GPP) (trademark) Long Term Evolution (LTE) (trademark) standard. The 5G standard is, for example, 5G New radio (NR). The radio frequency module 100 is, for example, a module that can support carrier aggregation and dual connectivity. The radio frequency module 100 is, for example, a transceiver module having a radio frequency circuit including a power amplifier, a transmission filter, an output matching circuit, a low-noise amplifier, a reception filter, and an input matching circuit, but is not limited to the transceiver module. The radio frequency module 100 may be, for example, a transmission module having a radio frequency circuit including a power amplifier, a transmission filter, and an output matching circuit, or a reception module having a radio frequency circuit including a low-noise amplifier, a reception filter, and an input matching circuit.

Each of the plurality of electronic components including the plurality of first electronic components 3 and the plurality of second electronic components 8 is, for example, an IC chip, a transmission filter, a reception filter, a duplexer, a surface-mount electronic component, a multiplexer, or a coupler. The IC chip is, for example, a power amplifier, a low-noise amplifier, a switch, or a controller. Each of the transmission filter and the reception filter is, for example, a surface acoustic wave filter, a bulk acoustic wave filter, or an LC filter. The electronic component may be an electronic component including a plurality of filters (for example, surface acoustic wave filters). The surface-mount electronic component is, for example, a chip inductor or a chip capacitor.

### 1.1 Mounting Substrate

The mounting substrate 1 has the first main surface 101 and the second main surface 102 opposing each other in the thickness direction D1 of the mounting substrate 1. The outer edge of the mounting substrate 1 is formed in, for example, a rectangular shape in plan view from the thickness direction D1 of the mounting substrate 1, but may be formed in a shape other than a rectangular shape.

The mounting substrate 1 includes a plurality of dielectric layers including the first dielectric layer 11 and the second dielectric layer 12 between the first main surface 101 and the second main surface 102. The mounting substrate 1 is a multilayer substrate in which a plurality of dielectric layers and a plurality of conductive layers are laminated. The plurality of conductive layers is formed in a predetermined pattern determined for each layer. Each of the plurality of conductive layers includes one or more conductive portions within a plane orthogonal to the thickness direction D1 of the mounting substrate 1. The mounting substrate 1 includes a plurality of via conductors. Each of the plurality of via conductors is an interlayer connection conductor that connects (conductive portions of) two conductive layers opposing each other in the thickness direction D1 of the mounting substrate 1.

The plurality of dielectric layers includes the first dielectric layer 11, the second dielectric layer 12, a third dielectric layer 13, a fourth dielectric layer 14, and a fifth dielectric layer 15. In the mounting substrate 1, the first dielectric layer 11, the second dielectric layer 12, the third dielectric layer 13, the fourth dielectric layer 14, and the fifth dielectric layer 15 are arranged in this order in the thickness direction D1 of the mounting substrate 1. The plurality of conductive layers includes a first conductive layer 21, a second conductive layer 22, a third conductive layer 23, a fourth conductive layer 24, a fifth conductive layer 25, and a sixth conductive layer 26. In the mounting substrate 1, the first conductive layer 21, the second conductive layer 22, the third conductive layer 23, the fourth conductive layer 24, the fifth conductive layer 25, and the sixth conductive layer 26 are arranged in this order in the thickness direction D1 of the mounting substrate 1. In the present embodiment, the first main surface 101 of the mounting substrate 1 includes part of a main surface 151 of the fifth dielectric layer 15 on the opposite side to the fourth dielectric layer 14 side. In the present embodiment, the second main surface 102 of the mounting substrate 1 includes part of a main surface 112 of the first dielectric layer 11 on the opposite side to the second dielectric layer 12 side. The plurality of via conductors includes a plurality of first via conductors V1, a plurality of second via conductors V2, a plurality of third via conductors V3, a plurality of fourth via conductors V4, and a plurality of fifth via conductors V5. The plurality of first via conductors V1 passes through the first dielectric layer 11. Each second via conductor V2 passes through the second dielectric layer 12. Each third via conductor V3 passes through the third dielectric layer 13. Each fourth via conductor V4 passes through the fourth dielectric layer 14. Each fifth via conductor V5 passes through the fifth dielectric layer 15.

In the present embodiment, each of the first dielectric layer 11 and the second dielectric layer 12 contains a resin and does not contain a glass fiber. Accordingly, each of the first dielectric layer 11 and the second dielectric layer 12 does not contain a glass cloth. In the present embodiment, a first multilayer body including the first dielectric layer 11 and the first conductive layer 21 is formed using first resin coated copper foil (RCC). More specifically, the first dielectric layer 11 is formed by curing a half-cured resin layer included in the first RCC. The half-cured resin layer included in the first RCC contains a resin and does not contain a glass fiber. The first conductive layer 21 is formed by patterning first copper foil included in the first RCC. Therefore, the material of the first conductive layer 21 contains copper. In the present embodiment, a second multilayer body including the second dielectric layer 12 and the second conductive layer 22 is formed using second RCC. More specifically, the second dielectric layer 12 is formed by curing a half-cured resin layer included in the second RCC. The half-cured resin layer included in the second RCC contains a resin and does not contain a glass fiber. The second conductive layer 22 is formed by patterning second copper foil included in the second RCC. Therefore, the material of the second conductive layer 22 contains copper.

The resin contained in each of the first dielectric layer 11 and the second dielectric layer 12 is, for example, an epoxy resin, a fluororesin, or a liquid crystal polymer. Each of the first dielectric layer 11 and the second dielectric layer 12 contains a filler. The filler is an inorganic filler. The material of the inorganic filler is, for example, SiO₂, BaSO₄, or Al₂O₃.

In the present embodiment, the third dielectric layer 13 is located on a side opposite to the first dielectric layer 11 when viewed from the second dielectric layer 12 in the thickness direction D1 of the mounting substrate 1. The third dielectric layer 13 contains a glass fiber and a resin. The glass fiber is, for example, at least one selected from the group consisting of E-glass, T-glass, S-glass, U-glass, NE-glass, quartz fiber fabric, and aramid fiber fabric. The third dielectric layer 13 contains a filler. The filler is an inorganic filler. The material of the inorganic filler is, for example, SiO₂, BaSO₄, or Al₂O₃. In the present embodiment, for example, a third multilayer body including the third dielectric layer 13, the third conductive layer 23, and the fourth conductive layer 24 is formed using a core substrate including a prepreg, third copper foil disposed on a first main surface of the prepreg, and fourth copper foil disposed on a second main surface of the prepreg. More specifically, the third conductive layer 23 is formed by patterning the third copper foil of the core substrate. The fourth conductive layer 24 is formed by patterning the fourth copper foil of the core substrate. Therefore, the material of each of the third conductive layer 23 and the fourth conductive layer 24 contains copper.

In the present embodiment, the material of each of the fourth dielectric layer 14 and the fifth dielectric layer 15 contains a resin and does not contain a glass fiber. In the present embodiment, a fourth multilayer body including the fourth dielectric layer 14 and the fifth conductive layer 25 is formed using third RCC. More specifically, the fourth dielectric layer 14 is formed by curing a half-cured resin layer included in the third RCC. The half-cured resin layer included in the third RCC contains a resin and does not contain a glass fiber. The fifth conductive layer 25 is formed by patterning fifth copper foil included in the third RCC. Therefore, the fifth conductive layer 25 contains copper. In the present embodiment, a fifth multilayer body including the fifth dielectric layer 15 and the sixth conductive layer 26 is formed using fourth RCC. More specifically, the fifth dielectric layer 15 is formed by curing a half-cured resin layer included in the fourth RCC. The half-cured resin layer included in the fourth RCC contains a resin and does not contain a glass fiber. The sixth conductive layer 26 is formed by patterning sixth copper foil included in the fourth RCC. Therefore, the material of the sixth conductive layer 26 contains copper.

The resin contained in each of the fourth dielectric layer 14 and the fifth dielectric layer 15 is, for example, an epoxy resin, a fluororesin, or a liquid crystal polymer. Each of the fourth dielectric layer 14 and the fifth dielectric layer 15 contains a filler. The filler is an inorganic filler. The material of the inorganic filler is, for example, SiO₂, BaSO₄, or Al₂O₃.

The thickness of each of the first dielectric layer 11, the second dielectric layer 12, the third dielectric layer 13, the fourth dielectric layer 14, and the fifth dielectric layer 15 is, for example, not less than 5 μm and not more than 50 μm. In the present embodiment, the first dielectric layer 11, the second dielectric layer 12, the fourth dielectric layer 14, and the fifth dielectric layer 15 have the same thickness, but may have different thicknesses from each other. In the present embodiment, from the viewpoint of suppressing warpage of the mounting substrate 1, it is preferable that a difference between the total thickness of the first dielectric layer 11 and the second dielectric layer 12 and the total thickness of the fourth dielectric layer 14 and the fifth dielectric layer 15 be small. The thickness of each of the first conductive layer 21, the second conductive layer 22, the third conductive layer 23, the fourth conductive layer 24, the fifth conductive layer 25, and the sixth conductive layer 26 is, for example, not less than 3 μm and not more than 30 μm. In the present embodiment, the first conductive layer 21, the second conductive layer 22, the third conductive layer 23, the fourth conductive layer 24, the fifth conductive layer 25, and the sixth conductive layer 26 have the same thickness, but may have different thicknesses from each other.

In the mounting substrate 1, the plurality of conductive portions included in the sixth conductive layer 26 includes a plurality of first pad electrodes (land electrodes) 261. The material of the plurality of first pad electrodes 261 contains copper.

In the mounting substrate 1, the plurality of conductive portions included in the first conductive layer 21 includes a plurality of second pad electrodes (land electrodes) 211 and a plurality of third pad electrodes (land electrodes) 212. The material of the plurality of second pad electrodes 211 and the plurality of third pad electrodes 212 contains copper.

In the present embodiment, one of the plurality of conductive portions included in the second conductive layer 22 constitutes the ground electrode 220. Therefore, the material of the ground electrode 220 contains copper. The ground electrode 220 is in contact with the external shield layer 6. More specifically, a side edge 223 of the ground electrode 220 is in contact with the external shield layer 6. Thus, the ground electrode 220 is directly connected to the external shield layer 6.

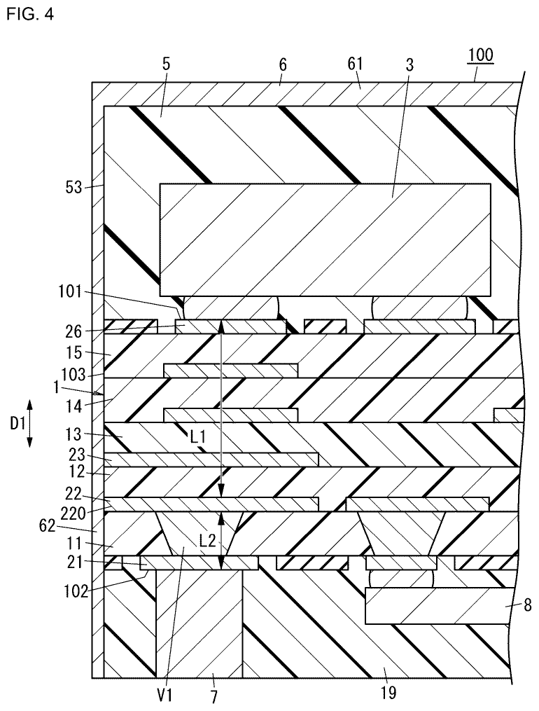

As illustrated in FIG. 4, in the thickness direction D1 of the mounting substrate 1, a distance L2 between the ground electrode 220 and the second main surface 102 of the mounting substrate 1 is shorter than a distance L1 between the ground electrode 220 and the first main surface 101 of the mounting substrate 1.

In the mounting substrate 1, the third conductive layer 23 includes a plurality of second ground electrodes 230 different from the ground electrodes 220 (hereinafter, also referred to as the first ground electrodes 220). Therefore, the material of the second ground electrode 230 contains copper. The second ground electrode 230 is in contact with the external shield layer 6. More specifically, a side edge 233 of the second ground electrode 230 is in contact with the external shield layer 6. Thus, the second ground electrode 230 is directly connected to the external shield layer 6.

Each of the plurality of via conductors including the plurality of first via conductors V1, the plurality of second via conductors V2, the plurality of third via conductors V3, the plurality of fourth via conductors V4, and the plurality of fifth via conductors V5 has conductivity. The material of each of the plurality of via conductors contains copper.

The first resist layer 17 is disposed on the main surface 151 of the fifth dielectric layer 15 on the opposite side to the fourth dielectric layer 14 side. The first resist layer 17 is patterned to expose the plurality of first pad electrodes 261. The first resist layer 17 has a plurality of openings 174 corresponding to the plurality of first pad electrodes 261 in a one-to-one manner. In plan view from the thickness direction D1 of the mounting substrate 1, each of the plurality of openings 174 is larger than the corresponding first pad electrode 261 among the plurality of first pad electrodes 261. The first resist layer 17 is, for example, a solder resist. The first resist layer 17 may be an over resist layer that covers part of each of the plurality of first pad electrodes 261.

The second resist layer 18 is disposed on the main surface 112 of the first dielectric layer 11 on the opposite side to the second dielectric layer 12 side. The second resist layer 18 is patterned to expose the plurality of second pad electrodes 211 and the plurality of third pad electrodes 212. A plurality of the second resist layers 18 has a plurality of openings 184 corresponding to the plurality of pad electrodes including the plurality of second pad electrodes 211 and the plurality of third pad electrodes 212 in a one-to-one manner. In plan view from the thickness direction D1 of the mounting substrate 1, each of the plurality of openings 184 is larger than the corresponding pad electrode among the plurality of pad electrodes. The second resist layer 18 is, for example, a solder resist. The second resist layer 18 may be an over resist layer that covers part of each of the plurality of pad electrodes.

### 1.2 First Electronic Component

As illustrated in FIGS. 1 and 2, the plurality of first electronic components 3 is disposed on the first main surface 101 of the mounting substrate 1. The expression “the first electronic component 3 is disposed on the first main surface 101 of the mounting substrate 1” includes the first electronic component 3 being mounted on (mechanically connected to) the first main surface 101 of the mounting substrate 1 and the first electronic component 3 being electrically connected to (an appropriate first pad electrode 261 of) the mounting substrate 1. Each of the plurality of first electronic components 3 is mechanically and electrically connected to the first main surface 101 of the mounting substrate 1 by a plurality of bonding portions 4. Each of the plurality of first electronic components 3 is a circuit component of a radio frequency circuit included in the radio frequency module 100. The material of the plurality of bonding portions 4 respectively corresponding to the plurality of first electronic components 3 is, for example, solder. The plurality of bonding portions 4 may be constituent elements of the first electronic components 3 or may be constituent elements interposed between the first electronic components 3 and the first main surface 101 of the mounting substrate 1.

In plan view from the thickness direction D1 of the mounting substrate 1, an outer edge of each of the plurality of first electronic components 3 has, for example, a rectangular shape. The plurality of first electronic components 3 includes a plurality of (twelve in FIG. 2) electronic components having a relatively large planar size and a plurality of (eighteen in FIG. 2) electronic components having a relatively small planar size. The electronic component having a relatively large planar size is, for example, an electronic component (e.g., a filter, a power amplifier, or a switch) including a substrate (e.g., a silicon substrate, a gallium arsenic substrate, a lithium tantalate substrate, or a lithium niobate substrate). The electronic component having a relatively small planar size is, for example, a surface-mount electronic component (e.g., a chip inductor or a chip capacitor).

### 1.3 First Resin Layer

The first resin layer 5 is disposed on the first main surface 101 of the mounting substrate 1 and covers the plurality of first electronic components 3, as illustrated in FIG. 1. The first resin layer 5 has electrical insulation properties. The first resin layer 5 contains a resin (for example, an epoxy resin). The first resin layer 5 may contain a filler in addition to the resin. 1.4 External Shield Layer

The external shield layer 6 covers the first resin layer 5 and the outer peripheral surface 103 of the mounting substrate 1. More specifically, the external shield layer 6 covers a main surface 51 of the first resin layer 5 on the opposite side to the mounting substrate 1 side, an outer peripheral surface 53 of the first resin layer 5, and the outer peripheral surface 103 of the mounting substrate 1. The external shield layer 6 includes a first shield portion 61 covering the main surface 51 of the first resin layer 5 and a second shield portion 62 covering the outer peripheral surface 53 of the first resin layer 5. The external shield layer 6 also covers an outer peripheral surface 193 of the second resin layer 19. In the external shield layer 6, the second shield portion 62 also covers the outer peripheral surface 193 of the second resin layer 19. In the radio frequency module 100, a main surface 191 of the second resin layer 19 on the opposite side to the mounting substrate 1 side is not covered with the external shield layer 6 and is exposed.

The external shield layer 6 has conductivity. In the radio frequency module 100, the external shield layer 6 is provided for the purpose of, for example, electromagnetic shielding between the inside and the outside of the radio frequency module 100. The external shield layer 6 has a multilayer structure in which a plurality of metal layers is laminated, but is not limited thereto, and may have a single metal layer structure. The metal layer includes one or more types of metals. When a shield layer has a multilayer structure in which a plurality of metal layers is laminated, the shield layer includes, for example, a first stainless steel layer, a Cu layer on the first stainless steel layer, and a second stainless steel layer on the Cu layer. The material of each of the first stainless steel layer and the second stainless steel layer is an alloy containing Fe, Ni, and Cr. The external shield layer 6 is, for example, a Cu layer in a case of being a single metal layer.

In the external shield layer 6, the second shield portion 62 is in contact with the ground electrode 220 of the mounting substrate 1. The external shield layer 6 is in contact with the ground electrode 220 of the mounting substrate 1, and is thus directly connected to the ground electrode 220 of the mounting substrate 1. Accordingly, the external shield layer 6 is connected to a ground terminal included in the plurality of external connection terminals 7 via the ground electrode 220 of the mounting substrate 1, for example.

### 1.5 External Connection Terminal

As illustrated in FIGS. 1 and 3, the plurality of external connection terminals 7 is disposed on the second main surface 102 of the mounting substrate 1. The expression “the external connection terminal 7 is disposed on the second main surface 102 of the mounting substrate 1” includes the external connection terminal 7 being mechanically connected to the mounting substrate 1 and the external connection terminal 7 being electrically connected to (an appropriate third pad electrode 212 of) the mounting substrate 1. In the present embodiment, the plurality of external connection terminals 7 corresponds to the plurality of third pad electrodes 212 of the mounting substrate 1 in a one-to-one manner. Each of the plurality of external connection terminals 7 overlaps the corresponding third pad electrode 212 among the plurality of third pad electrodes 212 and is connected to the corresponding third pad electrode 212. The material of the plurality of external connection terminals 7 is, for example, metal (for example, copper or a copper alloy). Each of the plurality of external connection terminals 7 is a columnar electrode (for example, a cylindrical electrode). The plurality of external connection terminals 7 is bonded to the third pad electrodes 212 by, for example, solder, but the present disclosure is not limited thereto. For example, the plurality of external connection terminals 7 may be bonded using a conductive adhesive (e.g., a conductive paste) or may be directly bonded.

The plurality of external connection terminals 7 includes a ground terminal. The ground terminal is, for example, a terminal that is electrically connected to a ground electrode of a circuit board included in the communication device 300 and is applied with a ground potential. The plurality of external connection terminals 7 includes an antenna terminal connected to an external antenna 310 included in the communication device 300 (see FIG. 5), a signal input terminal, a signal output terminal, and a control terminal. The signal input terminal, signal output terminal, and control terminal are connected to a signal processing circuit 301 of the communication device 300.

At least one external connection terminal 7 among the plurality of external connection terminals 7 overlaps the ground electrode 220 in the thickness direction D1 of the mounting substrate 1. The external connection terminal 7 overlapping the ground electrode 220 is separated from the ground electrode 220 in the thickness direction D1 of the mounting substrate 1. In the radio frequency module 100, in plan view from the thickness direction D1 of the mounting substrate 1, the whole external connection terminal 7 overlaps part of the ground electrode 220, but the present disclosure is not limited thereto. Part of the external connection terminal 7 may overlap part of the ground electrode 220, or part of the external connection terminal 7 may overlap the whole ground electrode 220.

In the radio frequency module 100, the external connection terminal 7 overlapping the ground electrode 220 contains copper.

The external connection terminal 7 overlapping the ground electrode 220 is a ground terminal. The external connection terminal 7 overlapping the ground electrode 220 is connected to the ground electrode 220 via one third pad electrode 212 among the plurality of third pad electrodes 212 and one first via conductor V1 among the plurality of first via conductors V1.

The number of external connection terminals 7 overlapping one ground electrode 220 is not limited to one, and may be two or more.

### 1.6 Second Electronic Component

As illustrated in FIGS. 1 and 3, the plurality of second electronic components 8 is disposed on the second main surface 102 of the mounting substrate 1. The expression “the second electronic component 8 is disposed on the second main surface 102 of the mounting substrate 1” includes the second electronic component 8 being mounted on (mechanically connected to) the second main surface 102 of the mounting substrate 1 and the second electronic component 8 being electrically connected to (an appropriate second pad electrode 211 of) the mounting substrate 1. Each of the plurality of second electronic components 8 is mechanically and electrically connected to the second main surface 102 of the mounting substrate 1 by a plurality of bonding portions 9. Each of the plurality of second electronic components 8 is a circuit component of a radio frequency circuit included in the radio frequency module 100. The material of the plurality of bonding portions 9 respectively corresponding to the plurality of second electronic components 8 is, for example, solder. The plurality of bonding portions 9 may be constituent elements of the second electronic components 8 or may be constituent elements interposed between the second electronic components 8 and the second main surface 102 of the mounting substrate 1.

In plan view from the thickness direction D1 of the mounting substrate 1, an outer edge of each of the plurality of second electronic components 8 has, for example, a rectangular shape.

### 1.7 Second Resin Layer

The second resin layer 19 is disposed on the second main surface 102 of the mounting substrate 1 and covers the plurality of second electronic components 8, as illustrated in FIG. 1. The second resin layer 19 covers side surfaces of the plurality of external connection terminals 7. The second resin layer 19 has electrical insulation properties. The second resin layer 19 has electrical insulation properties. The second resin layer 19 contains a resin (for example, an epoxy resin). The second resin layer 19 may contain a filler in addition to the resin. The material of the second resin layer 19 is the same as the material of the first resin layer 5, but may be a different material. The second resin layer 19 covers the main surface of the second electronic component 8 on the opposite side to the mounting substrate 1 side, but is allowed not to cover the main surface of the second electronic component 8 on the opposite side to the mounting substrate 1 side.

### 2. Physical Properties of Mounting Substrate

### 2.1 Young's Modulus

In the present embodiment, the following relation is satisfied: [Young's modulus of solder resist]<[Young's modulus of resin layer of RCC]<[Young's modulus of prepreg]<[Young's modulus of each of first resin layer 5 and second resin layer 19]<[Young's modulus of copper].

In the present embodiment, the Young's moduli of the first dielectric layer 11, the second dielectric layer 12, the fourth dielectric layer 14, and the fifth dielectric layer 15 are, for example, about 9 GPa. In the present embodiment, the Young's modulus of the third dielectric layer 13 is, for example, about 19 GPa. In the present embodiment, the Young's modulus of the ground electrode 220 is, for example, about 123 GPa. In the present embodiment, the Young's moduli of the first resist layer 17 and the second resist layer 18 are, for example, about 2.4 GPa.

In the present embodiment, the Young's modulus of each of the first dielectric layer 11, the second dielectric layer 12, the fourth dielectric layer 14, and the fifth dielectric layer 15 is smaller than the Young's modulus of the dielectric layer (third dielectric layer 13) formed using a prepreg.

### 2.2 Coefficient of Linear Expansion

In the present embodiment, the following relation is satisfied: [coefficient of linear expansion of prepreg]<[coefficient of linear expansion of each of first resin layer 5 and second resin layer 19]<[coefficient of linear expansion of stainless steel]<coefficient of linear expansion of copper]<[coefficient of linear expansion of resin layer of RCC]<[coefficient of linear expansion of solder resist]. The coefficient of linear expansion of the prepreg is, for example, about 8×10⁻⁶/K. The coefficient of linear expansion of each of the first resin layer 5 and the second resin layer 19 is, for example, about 10×10⁻⁶/K to 14×10⁻⁶/K. The coefficient of linear expansion of the stainless steel is, for example, about 14.4×10⁻⁶/K. The coefficient of linear expansion of the copper is, for example, about 16.5×10⁻⁶/K. The coefficient of linear expansion of the resin layer of RCC is, for example, about 18×10⁻⁶/K. The coefficient of linear expansion of the solder resist is about 60×10⁻⁶/K.

In the present embodiment, the coefficient of linear expansion of each of the first dielectric layer 11, the second dielectric layer 12, the fourth dielectric layer 14, and the fifth dielectric layer 15 is, for example, about 18×10⁻⁶/K. In the present embodiment, the coefficient of linear expansion of the third dielectric layer 13 is, for example, about 8×10⁻⁶/K. In the present embodiment, the coefficient of linear expansion of the ground electrode 220 is, for example, about 16.5×10⁻⁶/K.

In the present embodiment, a difference between the coefficient of linear expansion of each of the first dielectric layer 11 and second dielectric layer 12 sandwiching therebetween the ground electrode 220 and the coefficient of linear expansion of the ground electrode 220 is smaller than a difference between the coefficient of linear expansion of the ground electrode 220 and the coefficient of linear expansion of the dielectric layer (third dielectric layer 13) formed using the prepreg.

### 3. Communication Device

As illustrated in FIG. 5, the communication device 300 includes the radio frequency module 100 and the signal processing circuit 301, to which the radio frequency module 100 is connected, for example. The communication device 300 further includes the antenna 310. The communication device 300 further includes a circuit board (not illustrated) on which the radio frequency module 100 is mounted. The circuit board is, for example, a printed wiring board. The circuit board includes a ground electrode to which a ground potential is applied. The radio frequency module 100 is configured to be able to amplify a reception signal input from the antenna 310 and output the amplified reception signal to the signal processing circuit 301, for example. The radio frequency module 100 is configured to be able to amplify a transmission signal input from the signal processing circuit 301 and output the amplified transmission signal to the antenna 310, for example. The radio frequency module 100 is controlled by, for example, the signal processing circuit 301 included in the communication device 300.

The signal processing circuit 301 includes an RF signal processing circuit 302 and a baseband signal processing circuit 303. The RF signal processing circuit 302 is, for example, a radio frequency integrated circuit (RFIC), and performs signal processing on a radio frequency signal. The RF signal processing circuit 302 performs signal processing such as up-conversion on a radio frequency signal (transmission signal) output from the baseband signal processing circuit 303, and outputs the radio frequency signal having been subjected to the signal processing. The RF signal processing circuit 302 performs signal processing such as down-conversion on a radio frequency signal (reception signal) output from the radio frequency module 100, and outputs the radio frequency signal having been subjected to the signal processing to the baseband signal processing circuit 303. The baseband signal processing circuit 303 is, for example, a baseband integrated circuit (BBIC). The baseband signal processing circuit 303 generates an I-phase signal and a Q-phase signal from a baseband signal. The baseband signal is, for example, an audio signal or an image signal input from the outside. The baseband signal processing circuit 303 performs IQ modulation processing by combining the I-phase signal and the Q-phase signal, and then outputs a transmission signal. In this case, the transmission signal is generated as a modulation signal (IQ signal) obtained by performing amplitude modulation on a carrier wave signal of a predetermined frequency at a period longer than a period of the carrier wave signal. The reception signal processed by the baseband signal processing circuit 303 is used as an image signal for image display or as an audio signal for a telephone call of a user of the communication device 300, for example.

### 4. Effects

The radio frequency module 100 according to Embodiment 1 includes the mounting substrate 1, the electronic components 3, the resin layer 5, and the external shield layer 6. The mounting substrate 1 has the first main surface 101 and the second main surface 102 opposing each other. The electronic components 3 are each disposed on the first main surface 101 of the mounting substrate 1. The resin layer 5 is disposed on the first main surface 101 of the mounting substrate 1 and covers the electronic components 3. The external shield layer 6 covers at least part of the outer peripheral surface 103 of the mounting substrate 1 and the resin layer 5. The mounting substrate 1 includes the first dielectric layer 11, the second dielectric layer 12, and the ground electrodes 220. The first dielectric layer 11 contains a resin and does not contain a glass fiber. The second dielectric layer 12 overlaps the first dielectric layer 11 in the thickness direction D1 of the mounting substrate 1 and is in contact with the first dielectric layer 11. The second dielectric layer 12 contains a resin and does not contain a glass fiber. The ground electrodes 220 are interposed between the first dielectric layer 11 and the second dielectric layer 12. The ground electrodes 220 are each directly connected to the external shield layer 6.

According to the above configuration, it is possible to improve the reliability of shielding properties. More specifically, according to the above-described configuration, since the first dielectric layer 11 contains a resin and does not contain a glass fiber, and the second dielectric layer 12 contains a resin and does not contain a glass fiber, a difference in the coefficient of linear expansion between the first dielectric layer 11 and the second dielectric layer 12 can be reduced while achieving a reduction in thickness of the mounting substrate 1, and the warpage of the mounting substrate 1 can be suppressed, as compared to a case where one of the first dielectric layer and the second dielectric layer is formed using a prepreg. Further, according to the above-described configuration, since a difference in the coefficient of linear expansion between each of the first dielectric layer 11 and second dielectric layer 12 and the ground electrode 220 can be reduced, the ground electrode 220 interposed between the first dielectric layer 11 and the second dielectric layer 12 and directly connected to the external shield layer 6 easily follows the behavior of the first dielectric layer 11 and the second dielectric layer 12 due to a temperature change. Therefore, according to the above-described configuration, stress applied to the ground electrode 220 can be reduced, disconnection is unlikely to occur near a connection portion between the ground electrode 220 and the external shield layer 6, and the reliability of shielding properties can be improved.

The radio frequency module 100 according to Embodiment 1 further includes the plurality of external connection terminals 7. The plurality of external connection terminals 7 is disposed on the second main surface 102 of the mounting substrate 1. At least one external connection terminal 7 among the plurality of external connection terminals 7 overlaps the ground electrode 220 in the thickness direction D1 of the mounting substrate 1. The ground electrode 220 contains copper. The external connection terminal 7 overlapping the ground electrode 220 contains copper.

According to the above-described configuration, the ground electrodes 220 are further unlikely to warp, and the reliability of shielding properties can be further improved as compared with a case where no external connection terminal 7 overlapping the ground electrode 220 is present in the thickness direction D1 of the mounting substrate 1.

In the radio frequency module 100 according to Embodiment 1, in the thickness direction D1 of the mounting substrate 1, the distance L2 between the ground electrode 220 and the second main surface 102 of the mounting substrate 1 is shorter than the distance L1 between the ground electrode 220 and the first main surface 101 of the mounting substrate 1.

According to the above-described configuration, the distance L2 between the ground electrode 220 directly connected to the external shield layer 6 and the second main surface 102 of the mounting substrate 1 can be further shortened, and thus the shielding properties can be further improved. More specifically, the distance between the ground electrode 220 and the ground terminal as the external connection terminal 7 overlapping the ground electrode 220 can be further shortened, and thus the shielding properties can be further improved.

In the radio frequency module 100 according to Embodiment 1, the second main surface 102 of the mounting substrate 1 includes the main surface 112 of the first dielectric layer 11 on the opposite side to the second dielectric layer 12 side.

According to the above configuration, the shielding properties can be further improved.

In the radio frequency module 100 according to Embodiment 1, the mounting substrate 1 further includes the third dielectric layer 13, the fourth dielectric layer 14, and the fifth dielectric layer 15. The third dielectric layer 13 contains a resin and a glass fiber. The fourth dielectric layer 14 contains a resin and does not contain a glass fiber. The fifth dielectric layer 15 contains a resin and does not contain a glass fiber. The first dielectric layer 11, the second dielectric layer 12, the third dielectric layer 13, the fourth dielectric layer 14, and the fifth dielectric layer 15 are arranged in this order in the thickness direction D1 of the mounting substrate 1.

According to the above configuration, it is possible to further suppress the warpage of the mounting substrate 1, and further improve the reliability of shielding properties.

The radio frequency module 100 according to Embodiment 1 further includes the second electronic components 8 different from the first electronic components 3 as the electronic components 3. The second electronic components 8 are each disposed on the second main surface 102 of the mounting substrate 1.

With the above-described configuration, the radio frequency module 100 can be miniaturized.

The radio frequency module 100 according to Embodiment 1 further includes the second resin layer 19 different from the first resin layer 5 as the resin layer 5. The second resin layer 19 is disposed on the second main surface 102 of the mounting substrate 1 and covers the second electronic components 8.

With the above-described configuration, it is possible to further suppress the warpage of the mounting substrate 1 while achieving a reduction in size of the radio frequency module 100.

The communication device 300 according to Embodiment 1 includes the radio frequency module 100 and the signal processing circuit 301. The signal processing circuit 301 is connected to the radio frequency module 100.

According to the above configuration, it is possible to improve the reliability of shielding properties.

### Embodiment 2

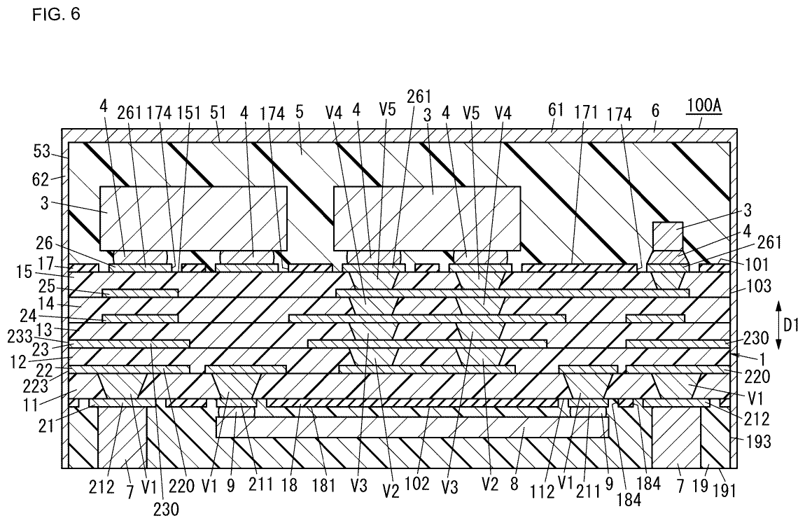

A radio frequency module 100A according to Embodiment 2 will be described with reference to FIG. 6. In the radio frequency module 100A according to Embodiment 2, the same constituent elements as those of the radio frequency module 100 according to Embodiment 1 (see FIGS. 1 to 5) are denoted by the same reference signs, and description thereof will be omitted.

### 1. Configuration

The radio frequency module 100A according to Embodiment 2 is different from the radio frequency module 100 according to Embodiment 1 in that the third dielectric layer 13 in the mounting substrate 1 contains a resin and does not contain a glass fiber.

In the present embodiment, the third dielectric layer 13 is formed not using a prepreg but using RCC. In short, in the present embodiment, the third dielectric layer 13 is formed using a resin layer of RCC, similarly to the first dielectric layer 11, the second dielectric layer 12, the fourth dielectric layer 14, and the fifth dielectric layer 15. The material of the third dielectric layer 13 is the same as the material of the first dielectric layer 11, the second dielectric layer 12, the fourth dielectric layer 14, and the fifth dielectric layer 15, but may be different from the material of the first dielectric layer 11, the second dielectric layer 12, the fourth dielectric layer 14, and the fifth dielectric layer 15.

In the radio frequency module 100A according to Embodiment 2, the mounting substrate 1 includes a plurality of dielectric layers including the first dielectric layer 11 and the second dielectric layer 12 between the first main surface 101 and the second main surface 102. The plurality of dielectric layers includes the first dielectric layer 11, the second dielectric layer 12, the third dielectric layer 13, the fourth dielectric layer 14, and the fifth dielectric layer 15. The number of pieces of the plurality of dielectric layers is not limited to five, and may be three, four, or six or more.

### 2. Effects

In the radio frequency module 100A according to Embodiment 2, the ground electrodes 220 interposed between the first dielectric layer 11 and the second dielectric layer 12 are each directly connected to the external shield layer 6, as in the radio frequency module 100 according to Embodiment 1, and therefore the reliability of shielding properties can be improved.

In the radio frequency module 100A according to Embodiment 2, the mounting substrate 1 includes the plurality of dielectric layers including the first dielectric layer 11 and the second dielectric layer 12 between the first main surface 101 and the second main surface 102. Each of the plurality of dielectric layers contains a resin and does not contain a glass fiber.

According to the above configuration, it is possible to further suppress the warpage of the mounting substrate 1, and further improve the reliability of shielding properties.

### Embodiment 3

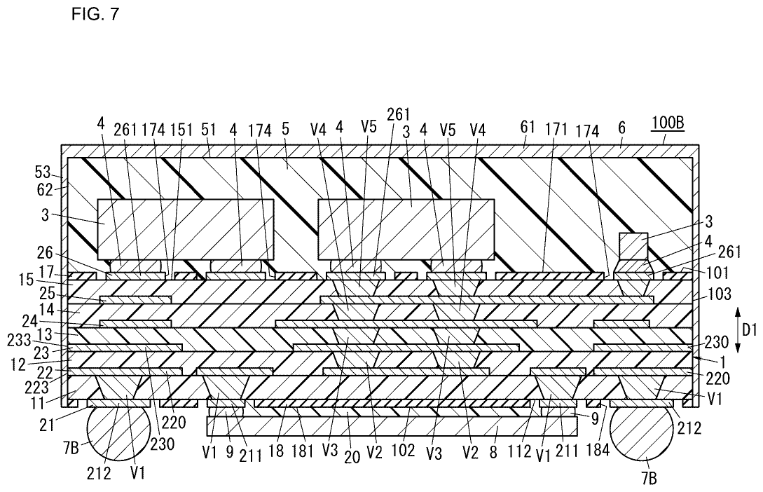

A radio frequency module 100B according to Embodiment 3 will be described with reference to FIG. 7. In the radio frequency module 100B according to Embodiment 3, the same constituent elements as those of the radio frequency module 100 according to Embodiment 1 (see FIGS. 1 to 5) are denoted by the same reference signs, and description thereof will be omitted.

### 1. Configuration

The radio frequency module 100B according to Embodiment 3 differs from the radio frequency module 100 according to Embodiment 1 in that the radio frequency module 100B includes a plurality of external connection terminals 7B instead of the plurality of external connection terminals 7 in the radio frequency module 100 according to Embodiment 1. The radio frequency module 100B is different from the radio frequency module 100 in that the radio frequency module 100B does not include the second resin layer 19 in the radio frequency module 100.

Each of the plurality of external connection terminals 7B is a ball bump. The material of the ball bumps constituting the plurality of external connection terminals 7B contains, for example, copper or solder. The solder is, for example, SnAgCu. The coefficient of linear expansion of SnAgCu is, for example, about 21×10⁻⁶/K to 22×10⁻⁶/K.

The radio frequency module 100B includes an underfill portion 20. The underfill portion 20 is interposed between the second electronic component 8 and the second main surface 102 of the mounting substrate 1. The second electronic component 8 is an IC chip and is mounted by flip chip bonding on the second main surface 102 of the mounting substrate 1.

### 2. Effects

In the radio frequency module 100B according to Embodiment 3, the ground electrodes 220 interposed between the first dielectric layer 11 and the second dielectric layer 12 are each directly connected to the external shield layer 6, as in the radio frequency module 100 according to Embodiment 1, and therefore the reliability of shielding properties can be improved.

The radio frequency module 100B according to Embodiment 3 further includes the plurality of external connection terminals 7. The plurality of external connection terminals 7 is disposed on the second main surface 102 of the mounting substrate 1. At least one external connection terminal 7 among the plurality of external connection terminals 7 overlaps the ground electrode 220 in the thickness direction D1 of the mounting substrate 1. The ground electrode 220 contains copper. The external connection terminal 7 overlapping the ground electrode 220 contains at least one of copper and solder.

According to the above-described configuration, the ground electrodes 220 are further unlikely to warp, and the reliability of shielding properties can be further improved as compared with a case where no external connection terminal 7B overlapping the ground electrode 220 is present in the thickness direction D1 of the mounting substrate 1.

### Embodiment 4

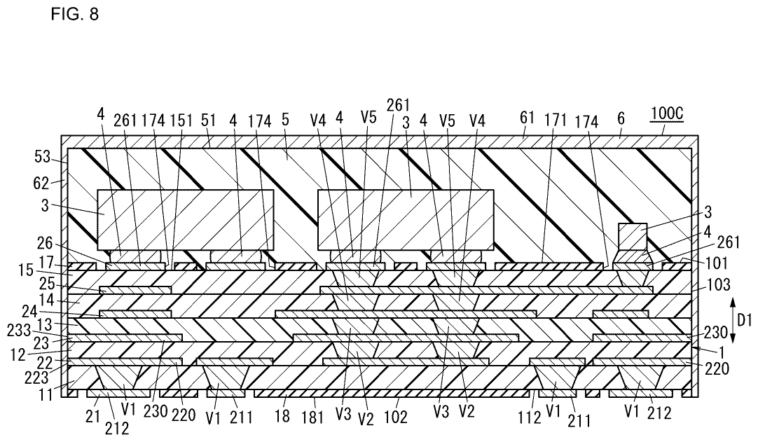

A radio frequency module 100C according to Embodiment 4 will be described with reference to FIG. 8. In the radio frequency module 100C according to Embodiment 4, the same constituent elements as those of the radio frequency module 100 according to Embodiment 1 (see FIGS. 1 to 5) are denoted by the same reference signs, and description thereof will be omitted.

### 1. Configuration

The radio frequency module 100C according to Embodiment 4 differs from the radio frequency module 100 according to Embodiment 1 in that the radio frequency module 100C does not include any of the second electronic component 8 disposed on the second main surface 102 of the mounting substrate 1, the plurality of external connection terminals 7, and the second resin layer 19 in the radio frequency module 100 according to Embodiment 1.

### 2. Effects

In the radio frequency module 100C according to Embodiment 4, the ground electrodes 220 interposed between the first dielectric layer 11 and the second dielectric layer 12 are each directly connected to the external shield layer 6, as in the radio frequency module 100 according to Embodiment 1, and therefore the reliability of shielding properties can be improved.

Embodiments 1 to 4 and the like described above are each merely one of various embodiments of the present disclosure. Embodiments 1 to 4 and the like described above can be variously modified in accordance with design and the like and may be appropriately combined as long as the feature of the present disclosure can be achieved.

For example, each of the first dielectric layer 11 and the second dielectric layer 12 may be configured not to include a filler.

For example, the external shield layer 6 is not limited to the form of covering the whole outer peripheral surface 103 of the mounting substrate 1 and the resin layer 5, and it is sufficient for the external shield layer 6 to cover at least part of the outer peripheral surface 103 of the mounting substrate 1 and the resin layer 5.

In the radio frequency modules 100, 100A, 100B, and 100C, among the plurality of first electronic components 3, a main surface of at least one first electronic component 3 opposite to a main surface on the mounting substrate 1 side may be in contact with the external shield layer 6 without being covered with the first resin layer 5.

In the radio frequency modules 100 and 100A, the second resin layer 19 covers the main surface of the second electronic component 8 on the opposite side to the mounting substrate 1 side, but may be in the mode of not covering the main surface of the second electronic component 8 on the opposite side to the mounting substrate 1 side.

Part of the circuit components of a radio frequency circuit included in the radio frequency module may be constituted by one or more conductive portions of the mounting substrate 1.

Each of the radio frequency modules 100, 100B, and 100C may include three or more dielectric layers each formed by using RCC and located on the first main surface 101 side of the mounting substrate 1 and three or more dielectric layers (including the first dielectric layer 11 and the second dielectric layer 12) each formed by using RCC and located on the second main surface 102 side of the mounting substrate 1, as viewed from the third dielectric layer 13. In this case, the number of pieces of the three or more dielectric layers on the first main surface 101 side of the mounting substrate 1 as viewed from the third dielectric layer 13 is preferably equal to the number of pieces of the three or more dielectric layers on the second main surface side of the mounting substrate 1 as viewed from the third dielectric layer 13. In the radio frequency module 100B according to Embodiment 3 or the radio frequency module 100C according to Embodiment 4, the mounting substrate 1 may include a plurality of dielectric layers including the first dielectric layer 11 and the second dielectric layer 12 between the first main surface 101 and the second main surface 102, and each of the plurality of dielectric layers may be configured to include a resin and not to include a glass fiber, as in the radio frequency module 100A according to Embodiment 2.

The radio frequency module 100 according to Embodiment 1 may include the external connection terminal 7B of the radio frequency module 100B according to Embodiment 3 instead of at least one external connection terminal 7 among the plurality of external connection terminals 7.

The external connection terminal 7 overlapping the ground electrode 220 may contain both copper and solder.

The external connection terminal 7 overlapping the ground electrode 220 may be a terminal other than the ground terminal.

The communication device 300 may include a plurality of antennas including the antenna 310, and the plurality of antennas may be connected to the radio frequency module 100.

The communication device 300 may include any of the radio frequency modules 100A, 100B, and 100C instead of the radio frequency module 100.

### Aspects

The present specification discloses the following aspects.

A radio frequency module (100; 100A; 100B; 100C) according to a first aspect includes a mounting substrate (1), electronic components (3), a resin layer (5), and an external shield layer (6). The mounting substrate (1) has a first main surface (101) and a second main surface (102) opposing each other. The electronic components (3) are each disposed on the first main surface (101) of the mounting substrate (1). The resin layer (5) is disposed on the first main surface (101) of the mounting substrate (1) and covers the electronic components (3). The external shield layer (6) covers at least part of an outer peripheral surface (103) of the mounting substrate (1) and the resin layer (5). The mounting substrate (1) includes a first dielectric layer (11), a second dielectric layer (12), and ground electrodes (220). The first dielectric layer (11) contains a resin and does not contain a glass fiber. The second dielectric layer (12) overlaps the first dielectric layer (11) in a thickness direction (D1) of the mounting substrate (1) and is in contact with the first dielectric layer (11). The second dielectric layer (12) contains a resin and does not contain a glass fiber. The ground electrodes (220) are interposed between the first dielectric layer (11) and the second dielectric layer (12). The ground electrodes (220) are each directly connected to the external shield layer (6).

According to the above aspect, it is possible to improve the reliability of shielding properties.

The radio frequency module (100; 100A; 100B; 100C) according to a second aspect further includes, in the first aspect, a plurality of external connection terminals (7; 7B). The plurality of external connection terminals (7; 7B) is disposed on the second main surface (102) of the mounting substrate (1). At least one external connection terminal (7; 7B) among the plurality of external connection terminals (7; 7B) overlaps the ground electrode 220 in the thickness direction (D1) of the mounting substrate (1). The ground electrode (220) contains copper. The external connection terminal (7; 7B) overlapping the ground electrode (220) contains at least one of copper and solder.

According to the above aspect, it is possible to further improve the reliability of shielding properties.

The radio frequency module (100; 100A; 100B; 100C) according to a third aspect is based on the second aspect. In the radio frequency module (100; 100A; 100B; 100C), in the thickness direction (D1) of the mounting substrate (1), a distance between the ground electrode (220) and the second main surface (102) of the mounting substrate (1) is shorter than a distance between the ground electrode (220) and the first main surface (101) of the mounting substrate (1).

According to the above aspect, a distance (L2) between the ground electrode (220) directly connected to the external shield layer (6) and the second main surface (102) of the mounting substrate (1) can be further shortened, and thus the shielding properties can be further improved.

The radio frequency module (100; 100A; 100B; 100C) according to a fourth aspect is such that, in the second aspect, the second main surface (102) of the mounting substrate (1) includes a main surface (112) of the first dielectric layer (11) on a side opposite to the second dielectric layer (12) side.

According to the above aspect, the shielding properties can be further improved.

The radio frequency module (100; 100B; 100C) according to a fifth aspect is such that, in any one of the first to fourth aspects, the mounting substrate (1) further includes a third dielectric layer (13), a fourth dielectric layer (14), and a fifth dielectric layer (15). The third dielectric layer (13) contains a resin and a glass fiber. The fourth dielectric layer (14) contains a resin and does not contain a glass fiber. The fifth dielectric layer (15) contains a resin and does not contain a glass fiber. The first dielectric layer (11), the second dielectric layer (12), the third dielectric layer (13), the fourth dielectric layer (14), and the fifth dielectric layer (15) are arranged in this order in the thickness direction (D1) of the mounting substrate (1).

According to the above aspect, it is possible to further suppress the warpage of the mounting substrate (1), and further improve the reliability of shielding properties.

The radio frequency module (100A) according to a sixth aspect is such that, in any one of the first to fourth aspects, the mounting substrate (1) includes a plurality of dielectric layers including the first dielectric layer (11) and the second dielectric layer (12) between the first main surface (101) and the second main surface (102). Each of the plurality of dielectric layers contains a resin and does not contain a glass fiber.

According to the above aspect, it is possible to further suppress the warpage of the mounting substrate (1), and further improve the reliability of shielding properties.

The radio frequency module (100; 100A; 100B) according to a seventh aspect further includes, in any one of the first to sixth aspects, second electronic components (8). The second electronic component (8) is different from the first electronic component (3) as the electronic component (3). The second electronic components (8) are each disposed on the second main surface (102) of the mounting substrate (1).

According to the above aspect, the radio frequency module (100; 100A; 100B) can be miniaturized.

The radio frequency module (100; 100A) according to an eighth aspect further includes, in any one of the first to fourth aspects, a second resin layer (19) different from a first resin layer (5) as the resin layer (5). The second resin layer (19) is disposed on the second main surface (102) of the mounting substrate (1) and covers the second electronic components (8).

According to the above aspect, it is possible to further suppress the warpage of the mounting substrate (1) while achieving a reduction in size of the radio frequency module (100; 100A).

The radio frequency module (100; 100A; 100B; 100C) according to a ninth aspect is such that, in any one of the first to eighth aspects, each of the first dielectric layer (11) and the second dielectric layer (12) further includes a filler.

A communication device (300) according to a tenth aspect includes the radio frequency module (100; 100A; 100B; 100C) according to any one of the first to ninth aspects, and a signal processing circuit (301). The signal processing circuit (301) is connected to the radio frequency module (100; 100A; 100B; 100C).

According to the above aspect, it is possible to improve the reliability of shielding properties.

What is claimed is:

1. A radio frequency module, comprising:
a mounting substrate having a first main surface and a second main surface opposing each other;
an electronic component disposed on the first main surface of the mounting substrate;
a resin layer disposed on the first main surface of the mounting substrate and covering the electronic component; and
an external shield layer covering at least part of an outer peripheral surface of the mounting substrate and covering the resin layer, wherein
the mounting substrate includes
a first dielectric layer containing a resin and containing no glass fiber,
a second dielectric layer that overlaps the first dielectric layer in a thickness direction of the mounting substrate, is in contact with the first dielectric layer, contains a resin, and contains no glass fiber, and
a ground electrode interposed between the first dielectric layer and the second dielectric layer, and
the ground electrode is directly connected to the external shield layer.

2. The radio frequency module according to claim 1, further comprising:
a plurality of external connection terminals disposed on the second main surface of the mounting substrate, wherein
at least one external connection terminal among the plurality of external connection terminals overlaps the ground electrode in the thickness direction of the mounting substrate,
the ground electrode contains copper, and
the external connection terminal overlapping the ground electrode contains at least one of copper and solder.

3. The radio frequency module according to claim 2, wherein
a distance between the ground electrode and the second main surface of the mounting substrate is shorter than a distance between the ground electrode and the first main surface of the mounting substrate in the thickness direction of the mounting substrate.

4. The radio frequency module according to claim 2, wherein,
the second main surface of the mounting substrate includes a main surface of the first dielectric layer on a side opposite to the second dielectric layer side.

5. The radio frequency module according to claim 4, wherein
the mounting substrate further includes
a third dielectric layer containing a glass fiber and a resin,
a fourth dielectric layer containing a resin and containing no glass fiber, and
a fifth dielectric layer containing a resin and containing no glass fiber, and
the first dielectric layer, the second dielectric layer, the third dielectric layer, the fourth dielectric layer, and the fifth dielectric layer are arranged in this order in the thickness direction of the mounting substrate.

6. The radio frequency module according to claim 4, wherein
the mounting substrate includes a plurality of dielectric layers including the first dielectric layer and the second dielectric layer between the first main surface and the second main surface, and
each of the plurality of dielectric layers contains a resin and contains no glass fiber.

7. The radio frequency module according to claim 4, further comprising:
a second electronic component that is different from a first electronic component as the electronic component and is disposed on the second main surface of the mounting substrate.

8. The radio frequency module according to claim 7, further comprising:
a second resin layer that is different from a first resin layer as the resin layer, is disposed on the second main surface of the mounting substrate, and covers the second electronic component.

9. The radio frequency module according to claim 4, wherein
each of the first dielectric layer and the second dielectric layer includes a filler.

10. A communication device, comprising:
the radio frequency module according to claim 4; and
a signal processing circuit connected to the radio frequency module.

11. The radio frequency module according to claim 1, wherein
the mounting substrate further includes
a third dielectric layer containing a glass fiber and a resin,
a fourth dielectric layer containing a resin and containing no glass fiber, and
a fifth dielectric layer containing a resin and containing no glass fiber, and
the first dielectric layer, the second dielectric layer, the third dielectric layer, the fourth dielectric layer, and the fifth dielectric layer are arranged in this order in the thickness direction of the mounting substrate.

12. The radio frequency module according to claim 1, wherein
the mounting substrate includes a plurality of dielectric layers including the first dielectric layer and the second dielectric layer between the first main surface and the second main surface, and
each of the plurality of dielectric layers contains a resin and contains no glass fiber.

13. The radio frequency module according to claim 1, further comprising:
a second electronic component that is different from a first electronic component as the electronic component and is disposed on the second main surface of the mounting substrate.

14. The radio frequency module according to claim 2, wherein
the mounting substrate further includes
a third dielectric layer containing a glass fiber and a resin,
a fourth dielectric layer containing a resin and containing no glass fiber, and
a fifth dielectric layer containing a resin and containing no glass fiber, and
the first dielectric layer, the second dielectric layer, the third dielectric layer, the fourth dielectric layer, and the fifth dielectric layer are arranged in this order in the thickness direction of the mounting substrate.

15. The radio frequency module according to claim 2, wherein
the mounting substrate includes a plurality of dielectric layers including the first dielectric layer and the second dielectric layer between the first main surface and the second main surface, and
each of the plurality of dielectric layers contains a resin and contains no glass fiber.

16. The radio frequency module according to claim 2, further comprising:
a second electronic component that is different from a first electronic component as the electronic component and is disposed on the second main surface of the mounting substrate.

17. The radio frequency module according to claim 3, wherein
the mounting substrate further includes
a third dielectric layer containing a glass fiber and a resin,
a fourth dielectric layer containing a resin and containing no glass fiber, and
a fifth dielectric layer containing a resin and containing no glass fiber, and
the first dielectric layer, the second dielectric layer, the third dielectric layer, the fourth dielectric layer, and the fifth dielectric layer are arranged in this order in the thickness direction of the mounting substrate.

18. The radio frequency module according to claim 3, wherein
the mounting substrate includes a plurality of dielectric layers including the first dielectric layer and the second dielectric layer between the first main surface and the second main surface, and
each of the plurality of dielectric layers contains a resin and contains no glass fiber.

19. The radio frequency module according to claim 3, further comprising:
a second electronic component that is different from a first electronic component as the electronic component and is disposed on the second main surface of the mounting substrate.

20. A communication device, comprising:
the radio frequency module according to claim 1; and
a signal processing circuit connected to the radio frequency module.
